(19) United States
(12) Patent Application Publication
(10) Pub. No.: US 2007/0145478 A1
(43) Pub. Date: Jun. 28, 2007

(54) High voltage semiconductor device and method of manufacturing the same

(75) Inventor: Choul Joo Ko, Seoul (KR)

Correspondence Address: MAYER, BROWN, ROWE & MAW LLP, 1909 K STREET, N.W., WASHINGTON, DC, 20006, US

(73) Assignee: Dongbu Electronics Co., Ltd.

(21) Appl. No.: 11/644,899

(22) Filed: Dec. 26, 2006

(30) Foreign Application Priority Data
Dec. 28, 2005 (KR) 10-2005-0132332

(51) Int. Cl. H01L 29/76

(52) U.S. Cl. 257/341

(57) ABSTRACT

A high voltage semiconductor device includes a semiconductor substrate having a high voltage well region; a device isolation film to define an active region of the semiconductor substrate; a drift region formed at an outer periphery of the device isolation film; an impurities region formed under the bottom of the drift region to cover the device isolation film; a gate electrode formed in a predetermined region of the active region; and a source/drain region formed in the drift region on either side of the gate electrode.

### TECHNICAL FIELD

The disclosure relates to a high voltage semiconductor device; and, more particularly, to a high voltage semiconductor device capable of increasing a breakdown voltage by forming an impurities region under the bottom of a low voltage well region (drift region) and a manufacturing method thereof.

### BACKGROUND

In general, a semiconductor device uses a power supply which provides a voltage equal to or lower than 3.3 V in order to reduce power consumption and ensure reliability. However, it has also a high voltage transistor to be durable against a high input voltage supplied from outside to the interior of a circuit since it is reciprocally connected with peripheral devices in one system, the peripheral devices using a power supply which provides a high voltage greater than 5 V.

Such a high voltage transistor has the same structure as a normal MOS transistor, i.e., low voltage transistor and, further, it is formed simultaneously with the low voltage transistor through a series of processes.

Hereinafter, a high voltage semiconductor device including a conventional high voltage transistor and a manufacturing method thereof will be described as follows.

FIG. 1 is a cross sectional view of a high voltage semiconductor device according to a conventional method. As shown in FIG. 1, the high voltage semiconductor device according to the conventional method is constructed by a semiconductor substrate 1, a high voltage P-well 2 and a high voltage N-well (not shown) formed in the semiconductor substrate 1, a device isolation film 3 to define an active region, a gate electrode 4 formed at a predetermined region of the active region, a source/drain region 6 formed at either side of the gate electrode 4 and a drift region 5 which completely covers the large source/drain region 6 to stabilize a breakdown voltage. Herein, the device isolation film 3 is formed by forming a trench on the semiconductor substrate 1 and filling the inside of trench with an insulating film so that its depth is deep.

According to the manufacturing method, first, the high voltage N-well (not shown) and the high voltage P-well 2 are formed in the semiconductor substrate 1 by ion-implanting impurities. Thereafter, a mask is formed on the semiconductor substrate 1 to expose a device isolation region; and a substrate region exposed through the mask is etched to form a trench; and then an insulating film is deposited to fill the trench.

Sequentially, by applying a Chemical Mechanical Polishing (CMP) process to the insulating film, the device isolation film 3 of a trench shape is formed. With respect to this, by using a LOCOS method, after forming a device isolation mask which exposes the device isolation region on the substrate; and then performing channel stop ion implantation thereto, a field oxide film can be formed at the device isolation region through a thermal oxidation process.

Next, an N-drift region 5 and a P-drift region (not shown) are respectively formed on surfaces of the high voltage P-well 2 and the high voltage N-well. Herein, a low voltage well region becomes a drift region.

At this time, in a 0.35 μm semiconductor process which fabricates a gate electrode having a critical dimension (CD) of 0.35 μm, a drift region is formed by ion-implanting at 900 KeV, whereas, in a 0.25 μm semiconductor process fabricating a gate electrode which has a critical dimension (CD) of 0.25 μm, a drift region is formed by ion-implanting at 500 KeV. That is, it is because an-impurities region is formed largely and deeply under the bottom of the gate electrode with a short CD if ion implantation of impurities is performed at 500 KeV or more in a fabrication process of a highly integrated device of a 0.25 μm semiconductor. Therefore, it is apparent that the depth of the drift region in the process of fabricating the 0.25 μm semiconductor is shallower than that of the drift region in the process of fabricating the 0.35 μm semiconductor.

Thereafter, a gate oxide film and polysilicon are deposited on the semiconductor substrate and then patterned together so that the gate electrode 4 is formed.

Finally, the source/drain region 6 is formed at the drift region 5 of either side of the gate electrode 4 of a high voltage NMOS or PMOS by an ion implantation process. After that, sequential processes which include contact and wiring processes are performed.

However, according to the conventional high voltage semiconductor and the method thereof described above, in the 0.25 μm semiconductor process, in case that the drift region is formed by ion-implanting impurities into the device isolation film of a deep trench shape, there occurs a problem that the drift region 5 is not formed under the bottom of the device isolation film 3, as shown in I of FIG. 1.

It is because impurities are not implanted under the bottom of the device isolation film since, in a 0.25 μm CMOS semiconductor process, a maximum ion implantation energy level is only 500 KeV when impurities are ion-implanted to form a drift region.

Accordingly, in the 0.25 μm semiconductor process, an 18 V bidirectional high voltage semiconductor can not be implemented in case that the drift region is formed simply by implanting ion into the device isolation film.

### SUMMARY

There is, therefore, a need to provide a high voltage semiconductor capable of improving a breakdown voltage of the device by providing an impurities region under the bottom of a drift region to completely cover a device isolation film through an additional process of injecting high ion energy into an ion implantation process when performing the low voltage N-well process and a method thereof.

In accordance with an embodiment of the present invention, there is provided a high voltage semiconductor device including a semiconductor substrate having a high voltage well region; a device isolation film to define an active region of the semiconductor substrate; a drift region formed at an outer periphery of the device isolation film; an impurities region formed under the bottom of the drift region to cover the device isolation film; a gate electrode formed in a predetermined region of the active region; and a source/drain region formed in the drift region on either side of the gate electrode.

In accordance with another embodiment of the present invention, there is provided a method of forming a high voltage semiconductor device including forming a high voltage well region in a semiconductor substrate; forming a device isolation film in the semiconductor substrate; forming a drift region on a surface of the high voltage well region; forming an impurities region, by ion-implanting high-concentration impurities, under the bottom of the drift region to cover the device isolation film; forming a gate electrode on the semiconductor substrate; and forming a source/drain region in the drift region on either side of the gate electrode by ion-implanting impurities using the gate electrode as a mask.

In further embodiments, the device isolation film is formed by etching the semiconductor substrate and forming a trench and depositing an insulating film in the trench. The impurities region is formed under the bottom of the device isolation film to surround completely the device isolation film in the purpose of preventing a problem that the drift region is not formed under the trench-type device isolation film.

Specifically, other embodiments provide a method of forming a high voltage semiconductor device, wherein the high voltage well region is a high voltage N-well; and/or the drift region which is formed on a surface of the high voltage well region is a low voltage P-well; and/or in the step of forming the impurities region by ion-implanting high-concentration impurities under the bottom of the drift region, the impurities are ion implanted at a high energy level above 800 KeV˜900 KeV.

### BRIEF DESCRIPTION OF THE DRAWINGS

The above and other objects and features of the present invention will become apparent from the following description of various embodiments given in conjunction with the accompanying drawings, in which:

FIG. 1 is a cross sectional view of a conventional high voltage semiconductor device;

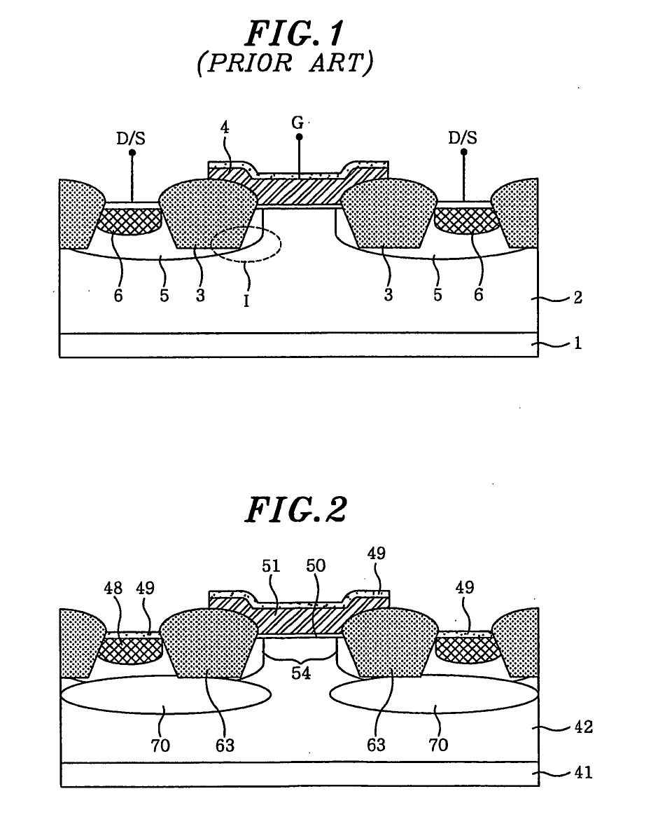

FIG. 2 shows a cross sectional view of a high voltage semiconductor device in accordance with an embodiment of the present invention; and

FIGS. 3A to 3E are cross sectional views illustrating a method of forming the high voltage semiconductor device in accordance with an embodiment of the present invention.

### DETAILED DESCRIPTION OF EMBODIMENTS

Hereinafter, embodiments of the present invention will be described in detail with reference to the accompanying drawings so that they can be readily implemented by those skilled in the art.

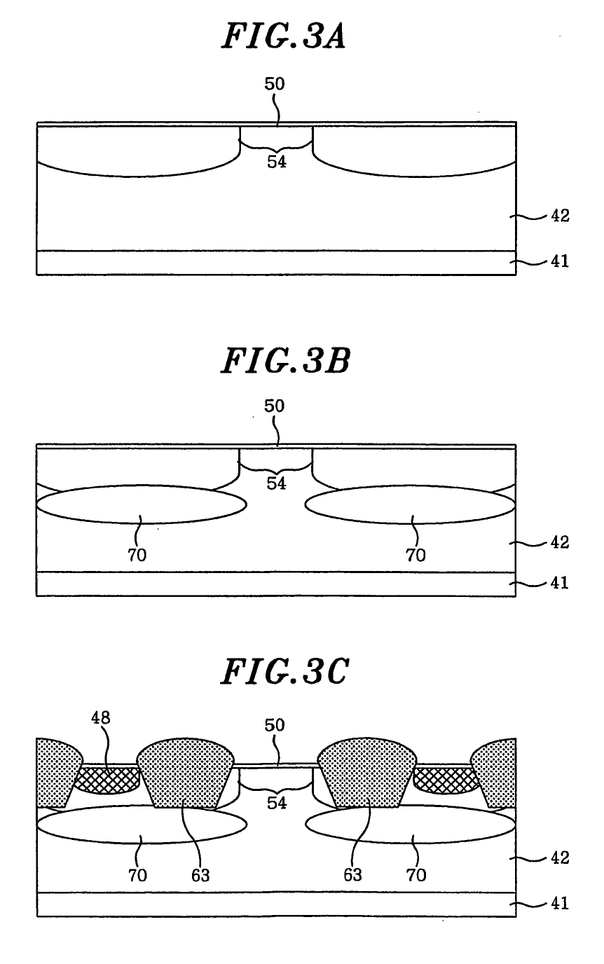

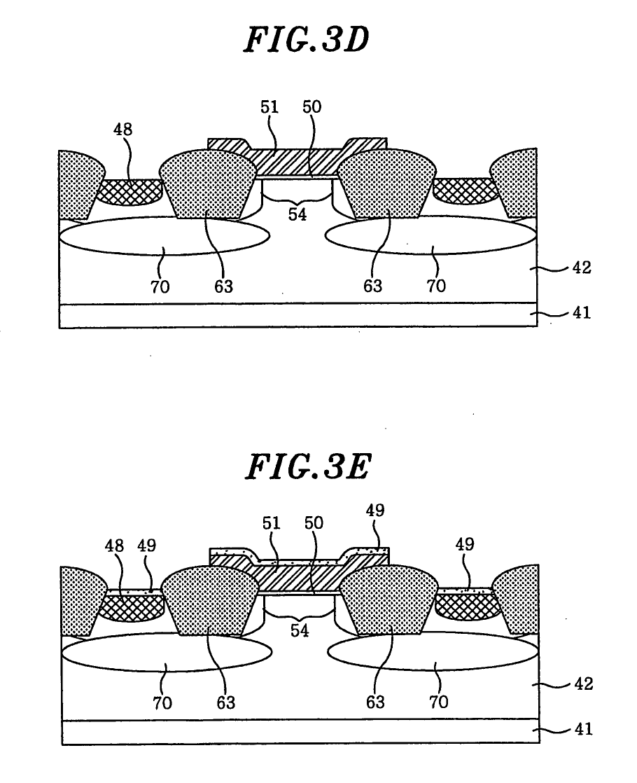

FIG. 2 describes a cross sectional view of a high voltage semiconductor device in accordance with an embodiment of the present invention; and FIGS. 3A to 3E are cross sectional views illustrating a method of forming the high voltage semiconductor device in accordance with an embodiment of the present invention.

As shown in FIG. 2, the high voltage semiconductor device in accordance with an embodiment of the present invention is constructed by a semiconductor substrate 41 having a high voltage P-well region 42 therein, a device isolation film 63 -to define an active region of the semiconductor substrate 41, a N-type drift region 54 formed at an outer periphery of the device isolation film 63, N-type impurities region 70 formed under the bottom of the drift region 54 to cover the device isolation film 63, a gate electrode 51 formed at a predetermined region of the active region and a source/drain region 48 formed at the drift region 54 of either side of the gate electrode 51.

Here, the N-type drift region 54 which is a low voltage N-well region is formed by ion-implanting N-type impurities, while the N-type impurities region is formed by ion-implanting high-concentration impurities at a high energy level above 800 KeV˜900 KeV.

The device isolation film 63 is formed by etching the semiconductor substrate 41 to form a trench and then filling the inside of the trench with an insulating film. Meanwhile, since the drift region 54 is not formed under the bottom of the device isolation film 63 by a conventional impurities ion-implantation, the impurities region 70 is additionally formed under the bottom of the device isolation film 63.

In particular, the drift region which is not formed under the bottom of the device isolation film 63 normally appears in a highly integrated semiconductor device where a critical dimension (CD) of a gate electrode is 0.25 μm and, therefore, by forming an impurities region under the bottom of a drift region in a highly integrated semiconductor device where a CD of a gate electrode is not greater than 0.25 μm, a breakdown voltage of the device can be greater than 18 V.

Meanwhile, although a high voltage well region is a high voltage P-well and a drift region formed on a surface of the high voltage well region is a low voltage N-well in an aforementioned preferred embodiment, the present invention is not limited thereto but can be applied to a case where a high voltage well region is a high voltage N-well and a drift region formed on a surface of the high voltage well region is a low voltage P-well. That is, a P-type impurities region is provided under the bottom of the low voltage P-well.

Hereinafter, the manufacturing method of the above high voltage semiconductor device will be described in detail as follows.

First, as illustrated in FIG. 3A, a buffer oxide film 50 is formed on the semiconductor substrate 41; and an ion implantation process is performed therein by using a first well mask (not shown). After that, an annealing process is carried out to form the high voltage P-well 42 and the high voltage N-well (not shown) in the semiconductor substrate 41.

Sequentially, an ion implantation process of impurities using a second well mask (not shown); and an annealing process are performed on the semiconductor substrate 41 to form the drift region 54 in the high voltage well region. That is, an N-type drift region is formed in the high voltage P-well while a P-type drift region is formed in the high voltage N-well.

At this time, in case of a process for forming a 0.25 μm highly integrated semiconductor device, a drift region becomes shallow because ion implantation to form a high voltage well region is carried out at an energy level 500 KeV Thereafter, as shown in FIG. 3B, the impurities region 70 is formed under the bottom of the drift region 54 by performing ion implantation of impurities at a high energy level of 900 KeV using a third well mask (not shown) on the semiconductor substrate 41.

Here, the second well mask for forming the drift region 54 and the third well mask for forming the impurities region 70 can be same or different. Further, the well mask which is used to form a drift region in the process for forming a 0.35 μm semiconductor device can be used as the third well mask.

In addition, in case that the high voltage well region is a high voltage P-well, the drift region formed on the surface of the high voltage well region is a low voltage N-well so that the impurities region is N-type impurities region. At this point, to form the impurities region, high-concentration phosphorus is implanted.

On the contrary, in case that the high voltage well region is a high voltage N-well, the drift region formed on the surface of the high voltage well region is a low voltage P-well, so that the impurities region is P-type impurities region.

Next, as described in FIG. 3C, a pad nitride film (not shown) is deposited on the semiconductor substrate 41; and the pad nitride film and the buffer oxide film 50 are patterned by a conventional photolithographic process to expose a device isolation region. After then, a trench is formed by etching the exposed substrate region; and an insulating film is deposited to fill the trench. Subsequently, by chemically-mechanically polishing (CMP) the insulating film until it has a predetermined thickness on the pad nitride film, the trench-shaped device isolation film (63) is formed. After that, the pad nitride film is removed.

Herein, although the device isolation film 63 is out of the drift region 54, it can be completely covered with the impurities region 70.

Sequentially, as shown in FIG. 3D, the gate electrode 51 is formed by depositing polysilicon and patterning it by using a dry etching process.

Meanwhile, in case of a process forming a 0.25 μm semiconductor device, the gate electrode 51 is formed to have a critical dimension (CD) of 0.25 μm.

Next, as shown in FIG. 3E, by ion-implanting high-concentration impurities using the gate electrode 51 as a mask, the source/drain region 48 is formed at the drift region 54 which is formed at either side of the gate electrode 51. In this way, a trenched channel is formed.

Finally, a silicide 49 is formed on the outside surfaces of the gate electrode 51 and the source/drain region 48 by performing a non-salicide process, thereby completing the high voltage transistor in accordance with the present invention.

Although not shown, a series of processes including contact and wiring processes are performed sequentially.

As described above, the high voltage semiconductor device according to embodiments of the present invention and the method of manufacturing the same have the following effects.

First, in order to overcome the problem that the drift region is not formed under the bottom of the device isolation film of a trench shape, embodiments of the present invention provides the impurities region under the bottom of the drift region to completely cover the device isolation film, thereby improving a breakdown voltage of the device.

Second, an additional process for forming the impurities region can be easily performed by injecting high ion energy into the existing ion implantation process when performing the low voltage N-well process, thereby forming the N-type impurities region under the bottom of the low voltage N-well or the device isolation film.

Third, since the proposed 18 V bidirectional high voltage semiconductor is formed simply by adding an implantation process of phosphorous having high ion energy into the ion implantation process for forming the low voltage N-well, a process which can be performed only in the 0.35 μm semiconductor process can be accomplished in the 0.25 μm semiconductor process. Therefore, according to the proposed device, an 18 V bidirectional device in the 0.35 μm semiconductor process can be performed in the 0.25 μm semiconductor process at a minimum cost.

While the invention has been shown and described with respect to various embodiments, it will be understood by those skilled in the art that various changes and modifications may be made without departing from the spirit and scope of the invention as defined in the following claims.

What is claimed is:

1. A high voltage semiconductor device, comprising:
a semiconductor substrate having a high voltage well region;
a device isolation film defining an active region of the semiconductor substrate;
a drift region formed at an outer periphery of the device isolation film;
an impurities region formed under the bottom of the drift region to cover the device isolation film;
a gate electrode formed in a predetermined region of the active region; and
a source/drain region formed in the drift region on either side of the gate electrode.

2. The high voltage semiconductor device of claim 1, wherein the impurities region is formed under the bottom of the device isolation film.

3. The high voltage semiconductor device of claim 1, wherein a critical dimension (CD) of the gate electrode is 0.25 μm.

4. The high voltage semiconductor device of claim 1, wherein the high voltage well region is a high voltage N-well; and the drift region formed on a surface of the high voltage well region is a low voltage P-well.

5. The high voltage semiconductor device of claim 1, wherein the high voltage well region is a high voltage P-well; and the drift region formed on a surface of the high voltage well region is a low voltage N-well.

6. The high voltage semiconductor device of claim 1, wherein the impurities region is an N-type impurities region formed by implanting phosphorus as high-concentration impurities.

7. A method of forming a high voltage semiconductor device, the method comprising the steps of:
forming a high voltage well region in a semiconductor substrate;
forming a device isolation film in the semiconductor substrate;
forming a drift region on a surface of the high voltage well region;
forming an impurities region, by ion-implanting high-concentration impurities, under the bottom of the drift region to cover the device isolation film;
forming a gate electrode on the semiconductor substrate; and
forming a source/drain region on the drift region on either side of the gate electrode by ion-implanting impurities using the gate electrode as a mask.

8. The method of claim 7, wherein the impurities region is formed under the bottom of the device isolation film.

9. The method of claim 8, wherein the device isolation film is formed by etching the semiconductor substrate and forming a trench and depositing an insulating film in the trench.

10. The method of claim 7, wherein a critical dimension (CD) of the gate electrode is 0.25 μm.

11. The method of claim 7, wherein, in the step of forming the impurities region by ion-implanting high-concentration impurities under the bottom of the drift region, the impurities are ion implanted at a high energy level above 800 KeV˜900 KeV.

12. The method of claim 7, wherein the high voltage well region is a high voltage P-well; and the drift region which is formed on a surface of the high voltage well region is a low voltage N-well.

13. The method of claim 7, wherein the high voltage well region is a high voltage N-well; and the drift region which is formed on a surface of the high voltage well region is a low voltage P-well.

14. The method of claim 7, wherein in the step of forming the impurities region by ion-implanting high-concentration impurities under the bottom of the drift region, phosphorus is implanted to form an N-type impurities region.

15. The method of claim 7, the method further comprising a step of forming a silicide film on surfaces of the gate electrode and the source/drain region after forming the source/drain region.

16. The method of claim 7, wherein the step of forming the impurities region is performed before the step of forming the device isolation film.

17. The method of claim 16, wherein the step of forming the drift region is performed before the step of forming the impurities region.

18. The method of claim 17, wherein the step of forming the drift region comprises a first ion implantation process at a first energy level; and
the step of forming the impurities region comprises a second ion implantation process at a second energy level higher than the first level.

19. The method of claim 17, wherein, in the step of forming the device isolation film, the bottom of the device isolation film is formed to be completely covered by at least one of the impurities region and the drift region.

20. The high voltage semiconductor device of claim 1, wherein the bottom of the device isolation film is completely covered by the impurities region.
